(19) United States
(12) Patent Application Publication
(10) Pub. No.: US 2025/0255150 A1
(43) Pub. Date: Aug. 7, 2025

(54) CURVED DISPLAY DEVICE, METHOD OF MANUFACTURING THE SAME, AND ELECTRONIC DEVICE

(71) Applicant: SAMSUNG DISPLAY CO., LTD., YONGIN-SI (KR)

(72) Inventors: Gyuseong Shim, Yongin-si (KR); Chang Hyung Lee, Yongin-si (KR); Jin Hyun, Yongin-si (KR)

(21) Appl. No.: 18/982,890

(22) Filed: Dec. 16, 2024

(30) Foreign Application Priority Data
Feb. 5, 2024 (KR) 10-2024-0017532

(51) Int. Cl. H10K 59/80; H05K 5/03; H10K 59/12; H10K 102/00

(52) U.S. Cl. CPC H10K 59/873; H05K 5/03; H10K 59/1201; H10K 2102/311

(57) ABSTRACT

An apparatus includes a display panel having a curved surface, a cover glass disposed on the curved surface of the display panel, and an adhesive layer disposed between the display panel and the cover glass. A creep strain of the adhesive layer is in a range of about 15 percent to about 50 percent at about 50 degrees Celsius.

### CROSS-REFERENCE TO RELATED APPLICATION(S)

This application claims priority under 35 U.S.C. § 119 to Korean Patent Application No. 10-2024-0017532, filed on Feb. 5, 2024, in the Korean Intellectual Property Office, the content of which is incorporated by reference for all purposes as if fully set forth herein.

### BACKGROUND

### 1. Technical Field

Embodiments relate to a display device, method of manufacturing the same, and an electronic device including the same. More particularly, embodiments relate to a curved display device, method of manufacturing the same, and an electronic device including the same.

### 2. Discussion of Related Art

The significance of display devices in connecting users with information is becoming increasingly apparent as information technology advances. Various types of display devices are widely used across different fields. For example, curved display devices are being developed to meet growing demands for interfaces in automotive applications, medical fields, and wearable devices.

### SUMMARY

Embodiments provide a curved display device with improved display quality.

Embodiments also provide a method of manufacturing a curved display device with improved display quality.

Embodiments also provide an electronic device including the curved display device.

Additional features of the inventive concepts will be set forth in the description which follows, and in part will be apparent from the description, or may be learned by practice of the inventive concepts.

An apparatus according to an embodiment may include a display panel having a curved surface, a cover glass disposed on the curved surface of the display panel, and an adhesive layer disposed between the display panel and the cover glass. A creep strain of the adhesive layer may be in a range of about 15 percent to about 50 percent at about 50 degrees Celsius.

In an embodiment, a storage modulus of the adhesive layer may be in a range of about 0.01 megapascal to about 0.1 megapascal at about 25 degrees Celsius.

In an embodiment, a storage modulus of the adhesive layer may be in a range of about 0.1 megapascal to about 0.5 megapascal at about 0 degrees Celsius.

In an embodiment, the adhesive layer may be curved in a first direction. A thickness deviation of the adhesive layer in a sample area may be less than about 5 micrometers.

In an embodiment, a thickness deviation of the adhesive layer may be determined in the sample area having a width of about 3 millimeters in a second direction, wherein the second direction may be substantially perpendicular to the first direction.

In an embodiment, the cover glass may be rigid.

In an embodiment, the curved display device may further include a polarizing layer disposed between the display panel and the adhesive layer.

In an embodiment, the display panel may include a display substrate including a base layer, a circuit element layer on the base layer, and a light emitting element layer on the circuit element layer, an encapsulation substrate on the display substrate, and a seal disposed between the display substrate and the encapsulation substrate, the seal surrounding the light emitting element layer in a plan view.

In an embodiment, the display panel may include a base layer, a circuit element layer disposed on the base layer, a light emitting element layer disposed on the circuit element layer, and a thin film encapsulation layer disposed on the light emitting element layer.

An apparatus according to an embodiment may include a display panel curved in a first direction, a cover glass disposed on the display panel and curved in the first direction, and an adhesive layer disposed between the display panel and the cover glass and curved in the first direction. A thickness deviation of the adhesive layer in an area having a width of about 3 millimeters in the first direction may be less than about 5 micrometers.

In an embodiment, a creep strain of the adhesive layer may be in a range of about 15 percent to about 50 percent at about 50 degrees Celsius. A storage modulus of the adhesive layer may be in a range of about 0.01 megapascal to about 0.1 megapascal at about 25 degrees Celsius.

In an embodiment, a storage modulus of the adhesive layer may be in a range of about 0.1 megapascal to about 0.5 megapascal at about 0 degrees Celsius.

In an embodiment, the cover glass may be rigid.

In an embodiment, the curved display device may further include a polarizing layer disposed between the display panel and the adhesive layer.

A method of manufacturing a curved display device may include disposing a display panel and an adhesive layer on a first seating surface of a first jig, the first seating surface being curved in a first direction, disposing a cover glass on a second seating surface of a second jig, the second seating surface being curved in the first direction to correspond to the first seating surface, and moving at least one of the first jig or the second jig and bonding the display panel and the cover glass using the adhesive layer. A creep strain of the adhesive layer bonding the display panel and the cover glass may be in a range of about 15 percent to about 50 percent at about 50 degrees Celsius.

In an embodiment, a storage modulus of the adhesive layer may be in a range of about 0.01 megapascal to about 0.1 megapascal at about 25 degrees Celsius.

In an embodiment, a storage modulus of the adhesive layer may be in a range of about 0.1 megapascal to about 0.5 megapascal at about 0 degrees Celsius.

In an embodiment, a thickness deviation of the adhesive layer bonding the display panel and the cover glass at an area having a width of about 3 millimeters in the first direction may be less than about 5 micrometers.

In an embodiment, the adhesive layer may be cured before bonding the display panel and the cover glass.

In an embodiment, the cover glass may be curved in the first direction and rigid.

In an embodiment, a polarizing layer may be disposed between the display panel and the adhesive layer.

An electronic device according to an embodiment may include a display device and a power supply configured to provide power to the display device. The display device may include a display panel having a curved surface, a cover glass disposed on the curved surface of the display panel, and an adhesive layer disposed between the display panel and the cover glass. A creep strain of the adhesive layer may be in a range of about 15 percent to about 50 percent at about 50 degrees Celsius.

According to embodiments, in a curved display device that is curved in at least one direction, an adhesive layer included in the curved display device may be free of a visible stain. Accordingly, a display quality of the curved display device may be improved.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the invention.

FIG. 1 and FIG. 2 are views schematically illustrating a display device according to an embodiment.

FIG. 3 is a view schematically illustrating an example of a display panel included in the display device of FIG. 1.

FIG. 4 is an enlarged view of area A of FIG. 3.

FIG. 5 is a view schematically illustrating an example of a display panel included in the display device of FIG. 1.

FIG. 6 and FIG. 7 are views schematically illustrating a method of manufacturing a display device according to an embodiment.

FIG. 8 is a block diagram illustrating an electronic device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to embodiments set forth herein. Rather, embodiments are provided so that this disclosure will be thorough and complete, and will fully convey the scope of the invention to those skilled in the art. Like reference numerals refer to like elements throughout.

It will be understood that when an element is referred to as being related to another element such as being “on” another element, the element can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers, and/or sections, these elements, components, regions, layers and/or sections should not be limited by these terms. These terms are used to distinguish elements, components, regions, layers, or sections from each other. Thus, “a first element,” “component,” “region,” “layer,” or “section” discussed below could be termed a second element, component, region, layer, or section without departing from the teachings herein.

The terminology used herein is for the purpose of describing particular aspects and is not intended to be limiting. As used herein, “a”, “an,” “the,” and “at least one” do not denote a limitation of quantity, and are intended to include both the singular and plural, unless the context indicates otherwise. For example, “an element” has the same meaning as “at least one element,” unless the context indicates otherwise. “At least one” is not to be construed as limiting “a” or “an.” “Or” means “and/or.” As used herein, a reference number may indicate a singular element or a plurality of the element. For example, a reference number labeling a singular form of an element within the drawing figures may be used to reference a plurality of the singular element within the text of specification.

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in a drawing is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, the thicknesses, the ratios, and the dimensions of the elements may be exaggerated for effective description of the technical contents. As such, variations from the shapes or sizes of the illustrations may be expected. Thus, embodiments described herein should not be construed as limited to the particular shapes or sizes of elements or regions as illustrated herein but are to include deviations in shapes and sizes that may result, for example, from manufacturing. For example, a region illustrated or described as flat may have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In the drawings, a first direction (x direction) may cross a second direction (y direction). In addition, a third direction (z direction) may cross each of the first direction and the second direction. The third direction (z direction) may be substantially perpendicular to a plane formed by the first direction and the second direction. However, the disclosure is not limited thereto.

Illustrative, non-limiting embodiments will be more clearly understood from the following detailed description in conjunction with the accompanying drawings.

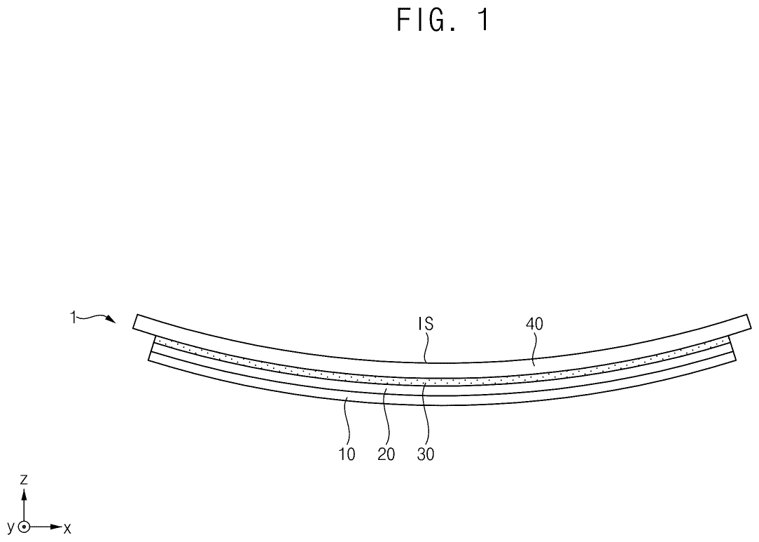

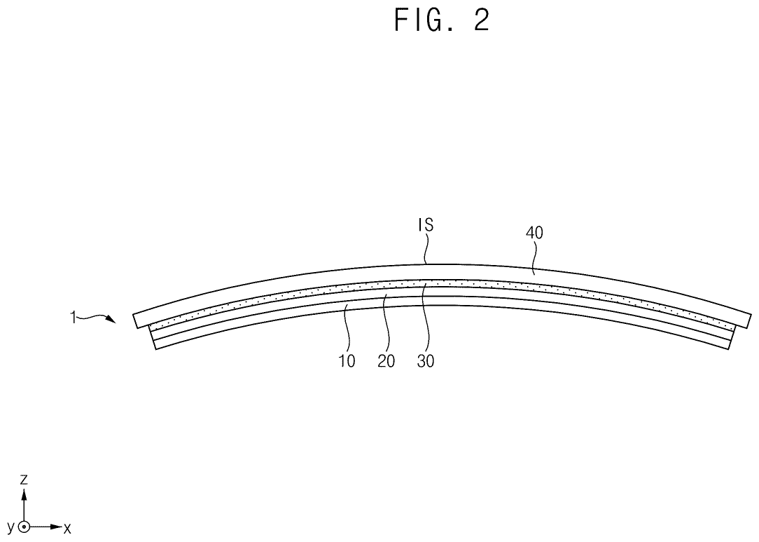

FIG. 1 and FIG. 2 are views schematically illustrating an apparatus according to an embodiment.

Referring to FIG. 1 and FIG. 2, a display device 1 may display an image through a display surface IS. The display device 1 may display the image in the third direction (e.g., +z direction) through the display surface IS. The display surface IS may correspond to an upper surface (or a front surface) of the display device 1. Hereinafter, the direction (e.g., +z direction) in which the display device 1 displays the image may be referred to as an upper direction.

The display device 1 may be a curved display device that is curved in at least one direction. For example, as illustrated in FIG. 1 and FIG. 2, the display device 1 may be curved in a first direction (e.g., +x direction). The display surface IS may be a curved surface that is curved in at least one direction. For example, the display device 1 may be a display device for vehicle placed in a fascia area of a vehicle or the like, but this is an example and embodiments are not limited thereto.

In an embodiment, as illustrated in FIG. 1, the display surface IS may be a concavely curved surface. In another embodiment, as illustrated in FIG. 2, the display surface IS may be a convexly curved surface. FIG. 1 and FIG. 2 illustrate that the display device 1 may be curved with a certain curvature, but this is an example and embodiments are not limited thereto. For example, the display device 1 may be curved to have a plurality of curved surface portions with different curvatures, or may be partially curved to have both a flat surface portion and a curved surface portion.

In an embodiment, the display device 1 may include a display panel 10, a polarizing layer 20, an adhesive layer 30, and a cover glass 40. The display panel 10, the polarizing layer 20, the adhesive layer 30, and the cover glass 40 may be sequentially stacked. Each of the display panel 10, the polarizing layer 20, the adhesive layer 30, and the cover glass 40 may be curved in at least one direction.

The display panel 10 may include a plurality of pixels for generating the image. Each of the pixels may include a pixel circuit. Each of the pixels may include a light emitting element. The pixel circuit may include at least one thin film transistor and at least one capacitor. The pixel circuit may generate a driving current, and may provide the driving current to the light emitting element. The light emitting element may emit light based on the driving current. For example, the light emitting element may include (or may be) an organic light emitting diode, an inorganic light emitting diode, a quantum dot light emitting diode, or a micro light emitting diode. The image may be generated by combining light emitted from each of the pixels.

The display panel 10 may include a curved surface. For example, an upper surface of the display panel 10 on which the adhesive layer 30 may be disposed, may be a curved surface. A lower surface of the display panel 10, disposed away from the cover glass 40 may be a curved surface, a flat surface, or a combination of curved and flat surfaces. For example, a shape of the lower surface of the display panel 10 is not limited.

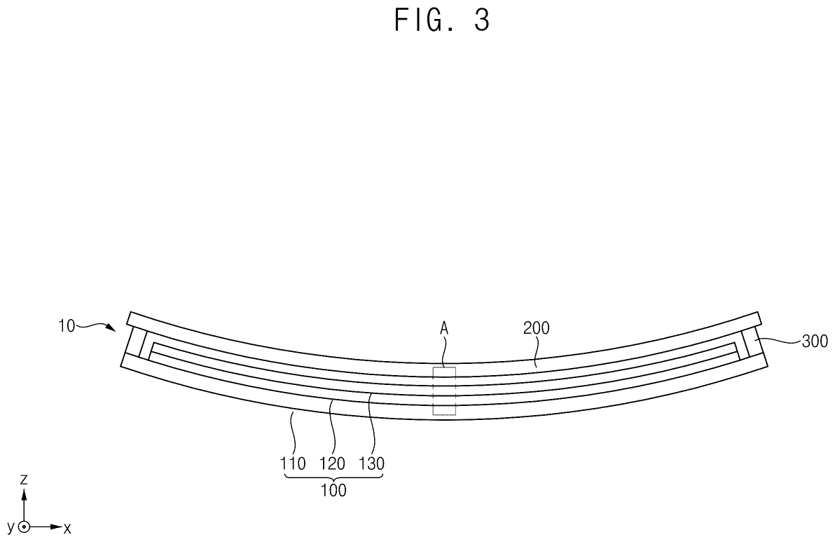

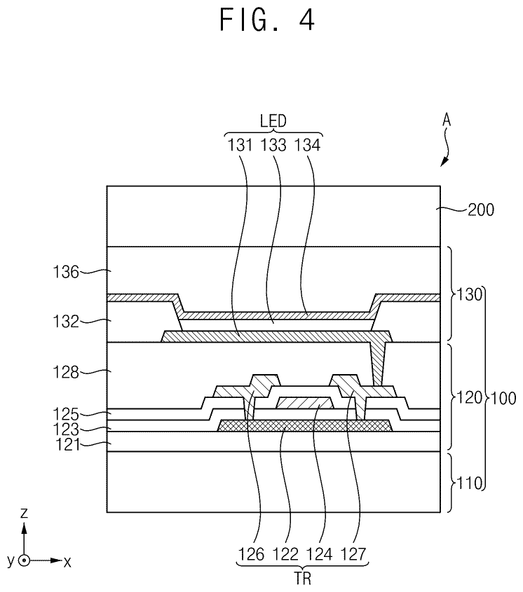

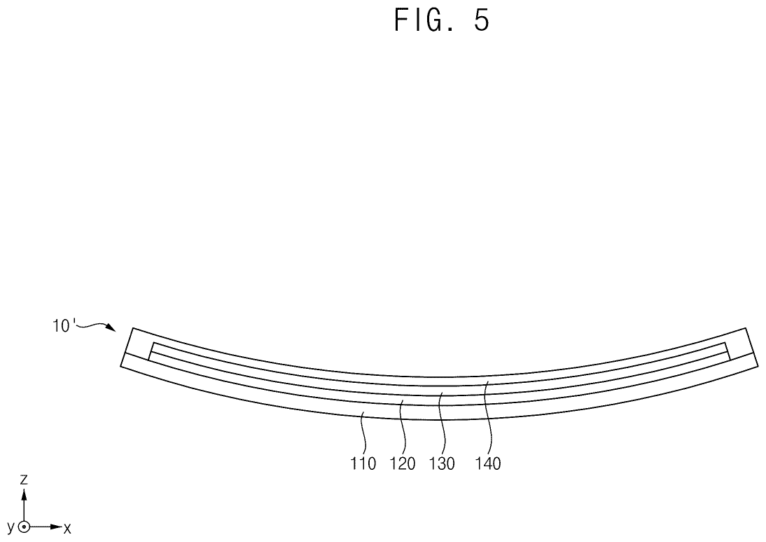

Hereinafter, the display panel 10 included in the display device 1 will be described in more detail with reference to FIG. 3, FIG. 4, and FIG. 5.

FIG. 3 is a view schematically illustrating an example of a display panel included in the display device of FIG. 1. FIG. 4 is an enlarged view of area A of FIG. 3.

Referring to FIG. 3 and FIG. 4, in an embodiment, the display panel 10 may include a display substrate 100, an encapsulation substrate 200, and a seal 300.

The display substrate 100 may include a base layer 110, a circuit element layer 120, and a light emitting element layer 130. The circuit element layer 120 may include the pixel circuit and a buffer layer 121, a gate insulating layer 123, an interlayer insulating layer 125, and a via insulating layer 128. The buffer layer 121, the gate insulating layer 123, the interlayer insulating layer 125, and the via insulating layer 128 may be insulating layers. The pixel circuit may include the thin film transistor TR and the capacitor (not illustrated). The light emitting element layer 130 may include the light emitting element LED and a pixel defining layer 132. The light emitting element LED may include a pixel electrode 131, an emission layer 133, and a common electrode 134. The pixel circuit and the light emitting element LED may form the pixel.

The base layer 110 may be an insulating substrate including, or formed of, a transparent material or a non-transparent material.

The buffer layer 121 may be disposed on the base layer 110. The buffer layer 121 may prevent or inhibit impurities such as oxygen or moisture from penetrating an upper portion of the base layer 110. The buffer layer 121 may include an inorganic material. In an embodiment, for example, the buffer layer 121 may include silicon oxide (SiO), silicon nitride (SiN), silicon oxynitride (SiON), silicon oxycarbide (SiOC), silicon carbonitride (SiCN), aluminum oxide (AlO), aluminum nitride (AlN), tantalum oxide (TaO), hafnium oxide (HfO), zirconium oxide (ZrO), or titanium oxide (TiO). These materials may be used alone or in a combination thereof. The buffer layer 121 may have a single-layered structure or a multi-layered structure including a plurality of insulating layers.

The thin film transistor TR may be disposed on the buffer layer 121. The thin film transistor TR may include an active layer 122, a gate electrode 124, a source electrode 126, and a drain electrode 127.

The active layer 122 may be disposed on the buffer layer 121. The active layer 122 may include an oxide semiconductor, a silicon semiconductor, or an organic semiconductor. In an embodiment, for example, the oxide semiconductor may include at least one selected from oxides of indium (In), gallium (Ga), tin (Sn), zirconium (Zr), vanadium (V), hafnium (Hf), cadmium (Cd), germanium (Ge), chromium (Cr), titanium (Ti), or zinc (Zn). The silicon semiconductor may include an amorphous silicon, or a polycrystalline silicon. The active layer 122 may include a source area, a drain area, and a channel area positioned between the source area and the drain area.

The gate insulating layer 123 may be disposed on the active layer 122. The gate insulating layer 123 may cover the active layer 122 on the buffer layer 121. The gate insulating layer 123 may include an inorganic insulating material.

The gate electrode 124 may be disposed on the gate insulating layer 123. The gate electrode 124 may overlap a channel area of the active layer 122. The gate electrode 124 may include a conductive material such as a metal, an alloy, a conductive metal nitride, a conductive metal oxide, or a transparent conductive material. In an embodiment, for example, the gate electrode 124 may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), or indium zinc oxide (IZO). These materials may be used alone or in a combination thereof. The gate electrode 124 may have a single-layered structure or a multi-layered structure including a plurality of conductive layers.

The interlayer insulating layer 125 may be disposed on the gate electrode 124. The interlayer insulating layer 125 may cover the gate electrode 124 and the gate insulating layer 123. The interlayer insulating layer 125 may include an inorganic insulating material.

The source electrode 126 and the drain electrode 127 may be disposed on the interlayer insulating layer 125. The source electrode 126 and the drain electrode 127 may be connected to the source area and the drain area of the active layer 122, respectively. For example, openings may be formed in the gate insulating layer 123 and the interlayer insulating layer 125 exposing portions of the active layer 122, and the source electrode 126 and the drain electrode 127 may be connected to the source area and the drain area of the active layer 122 through the openings. Each of the source electrode 126 and the drain electrode 127 may include a conductive material.

The via insulating layer 128 may be disposed on the source electrode 126, the drain electrode 127, and the interlayer insulating layer 125. The via insulating layer 128 may include an organic insulating material. In an embodiment, for example, the via insulating layer 128 may include photoresist, polyacryl-based resin, polyimide-based resin, polyamide-based resin, siloxane-based resin, acryl-based resin, or epoxy-based resin. These materials may be used alone or in a combination thereof.

FIG. 4 illustrates that the circuit element layer 120 includes four insulating layers and three conductive layers, but this is an example and embodiments are not limited thereto. For example, the circuit element layer 120 may include five or more insulating layers and four or more conductive layers.

The pixel electrode 131 may be disposed on the via insulating layer 128. The pixel electrode 131 may include a conductive material. The pixel electrode 131 may have a single-layered structure or a multi-layered structure including a plurality of conductive layers. The pixel electrode 131 may be connected to the drain electrode 127 through a contact hole formed in the via insulating layer 128. Accordingly, the pixel electrode 131 may be electrically connected to the thin film transistor TR.

The pixel defining layer 132 may be disposed on a portion of the pixel electrode 131 and the via insulating layer 128. The pixel defining layer 132 may cover a peripheral portion of the pixel electrode 131, and may define a pixel opening exposing a central portion of the pixel electrode 131. The pixel defining layer 132 may include an organic insulating material.

The emission layer 133 may be disposed on the pixel electrode 131. The emission layer 133 may be disposed in the pixel opening of the pixel defining layer 132. In some embodiments, the emission layer 133 may include at least one of an organic light emitting material or quantum dot.

In an embodiment, the organic light emitting material may include a low molecular organic compound or a high molecular organic compound. Examples of the low molecular organic compound may include copper phthalocyanine, N,N′-diphenylbenzidine, or tris-(8-hydroxyquinoline)aluminum. Examples of the high molecular organic compound may include poly(3,4-ethylenedioxythiophene), polyaniline, or poly-phenylenevinylene, polyfluorene. These materials may be used alone or in a combination thereof.

In an embodiment, the quantum dot may include a core including a Group II-VI compound, a Group III-V compound, a Group IV-VI compound, a Group IV element, and/or a Group IV compound. In an embodiment, the quantum dot may have a core-shell structure including the core and a shell surrounding the core. The shell may serve as a protection layer for preventing or inhibiting the core from being chemically denatured to maintain semiconductor characteristics, and may serve as a charging layer for imparting electrophoretic characteristics to the quantum dot.

The common electrode 134 may be disposed on the emission layer 133. The common electrode 134 may also be disposed on the pixel defining layer 132. The common electrode 134 may include a conductive material. The pixel electrode 131, the emission layer 133, and the common electrode 134 may form the light emitting element LED. The light emitting element LED may further include various functional layers (e.g., a hole injection layer, a hole transport layer, an electron transport layer, or an electron injection layer) disposed between the pixel electrode 131 and the emission layer 133, or between the emission layer 133 and the common electrode 134.

In an embodiment, the light emitting element layer 130 may further include a capping layer 136 disposed on the common electrode 134. The capping layer 136 may include an inorganic insulating material or an organic insulating material.

The encapsulation substrate 200 may be disposed on the display substrate 100. The encapsulation substrate 200 may be disposed in the upper direction (e.g., +z direction) from the display substrate 100. The encapsulation substrate 200 may be disposed to face the base layer 110 with the light emitting element layer 130 interposed therebetween. The encapsulation substrate 200 may cover the light emitting element layer 130 to protect the light emitting element layer 130. A gap may be formed between the light emitting element layer 130 and the encapsulation substrate 200. For example, a filler may be disposed between the light emitting element layer 130 and the encapsulation substrate 200.

The seal 300 may be disposed between the base layer 110 and the encapsulation substrate 200. The seal 300 may be disposed at an edge portion disposed between the base layer 110 and the encapsulation substrate 200. The seal 300 may surround the light emitting element layer 130 in a plan view (not shown). The seal 300 may bond the base layer 110 and the encapsulation substrate 200 to each other, and may prevent or inhibit moisture or the like from penetrating into the display panel 10 from a side of the display panel 10. For example, the seal 300 may include a frit or the like.

FIG. 5 is a view schematically illustrating an example of a display panel included in the display device of FIG. 1.

Referring to FIG. 5, in an embodiment, a display panel 10′ may include the base layer 110, the circuit element layer 120, the light emitting element layer 130, and a thin film encapsulation layer 140. The display panel 10′ of FIG. 5 may be substantially the same as or similar to the display panel 10 of FIG. 4. Repetitive descriptions thereof may be omitted or simplified. Referring to FIG. 5, an encapsulation member for covering the light emitting element layer 130 may be formed of the thin film encapsulation layer 140.

The thin film encapsulation layer 140 may be disposed on the base layer 110. The thin film encapsulation layer 140 may cover the light emitting element layer 130. The thin film encapsulation layer 140 may include at least one inorganic encapsulation layer and at least one organic encapsulation layer. In an embodiment, the thin film encapsulation layer 140 may include a first inorganic encapsulation layer disposed on the light emitting element layer 130, an organic encapsulation layer disposed on the first inorganic encapsulation layer, and a second inorganic encapsulation layer disposed on the organic encapsulation layer. The organic encapsulation layer may cover an entire surface of the light emitting element layer 130.

Referring again to FIG. 1 and FIG. 2, the polarizing layer 20 may be disposed on the display panel 10. The polarizing layer 20 may be disposed in the upper direction (e.g., +z direction) from the display panel 10. The polarizing layer 20 may reduce reflection of light incident from the outside. That is, the polarizing layer 20 may reduce an external light reflectance of the display device 1.

In an embodiment, various functional layers (e.g., a touch sensing layer, a color filter layer, a light collecting layer, or an adhesive layer) may be disposed between the display panel 10 and the polarizing layer 20.

The cover glass 40 may be disposed on the polarizing layer 20. The cover glass 40 may be disposed in the upper direction (e.g., +z direction) from the polarizing layer 20. In an embodiment, the cover glass 40 may be rigid. For example, the cover glass 40 may be manufactured to have a curved shape using a rigid material (e.g., glass or quartz). The cover glass 40 may protect the display panel 10 and the polarizing layer 20 from an external environment. The cover glass 40 may be transparent.

The adhesive layer 30 may be disposed between the polarizing layer 20 and the cover glass 40. That is, the adhesive layer 30 may be disposed between the display panel 10 and the cover glass 40. The adhesive layer 30 may attach the cover glass 40 to the polarizing layer 20 and the display panel 10. The adhesive layer 30 may be transparent. For example, the adhesive layer 30 may include an adhesive such as an optical clear adhesive (OCA) or a pressure sensitive adhesive (PSA).

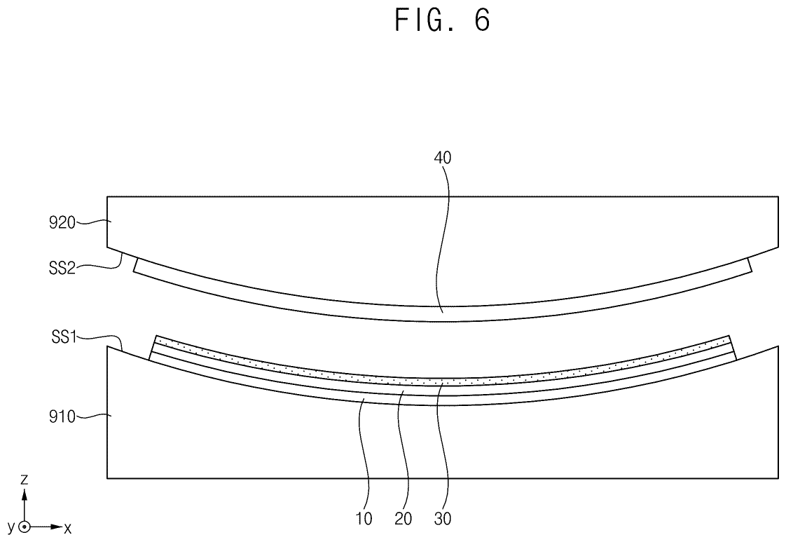

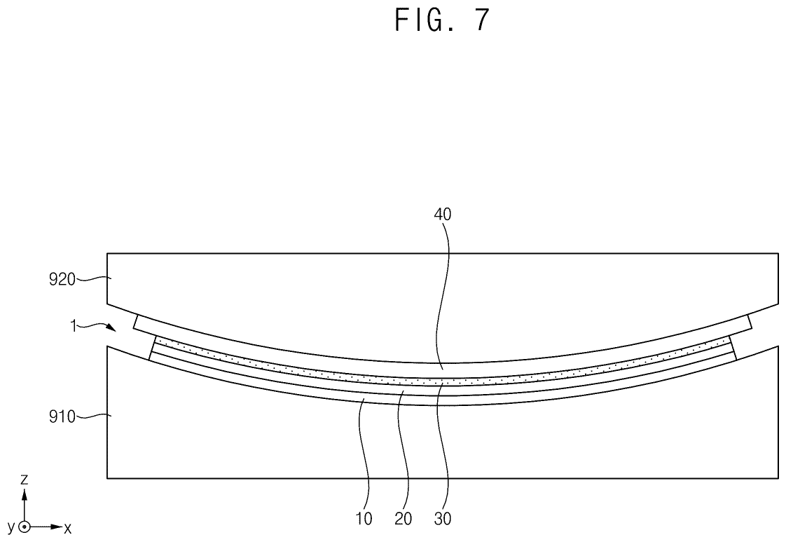

FIG. 6 and FIG. 7 are views schematically illustrating a method of manufacturing a display device according to an embodiment.

For example, FIG. 6 and FIG. 7 may illustrate a method of manufacturing the display device 1 having the display surface IS of FIG. 1. For example, the display surface IS may be concavely curved. Hereinafter, repeated descriptions thereof may be omitted or simplified.

Referring to FIG. 6 and FIG. 7, a structure in which the display panel 10, the polarizing layer 20, and the adhesive layer 30 may be stacked (hereinafter, referred to as a stacked structure) may be prepared. The display panel 10, the polarizing layer 20, and the adhesive layer 30 may be sequentially stacked in the upward direction (e.g., +z direction).

The stacked structure including the display panel 10, the polarizing layer 20, and the adhesive layer 30 may be disposed on a first seating surface SS1 of a first jig 910. The first seating surface SS1 of the first jig 910 may be curved in the first direction (e.g., ±x direction). As illustrated in FIG. 6, the first seating surface SS1 may be a concavely curved surface. The stacked structure may be seated in the upper direction (e.g., +z direction) from the first jig 910.

The cover glass 40 may be disposed on a second seating surface SS2 of a second jig 920. For example, the cover glass 40 may be secured to the second seating surface SS2 by vacuum pressure applied to an upper surface of the cover glass 40. The second seating surface SS2 of the second jig 920 may face the first seating surface SS1 of the first jig 910. For example, the first seating surface SS1 may be an upper surface of the first jig 910, and the second seating surface SS2 may be a lower surface of the second jig 920.

The second seating surface SS2 of the second jig 920 may be curved in the first direction (e.g., ±x direction) to correspond to the first seating surface SS1 of the first jig 910. As illustrated in FIG. 6, the second seating surface SS2 may be a convexly curved surface. The cover glass 40 may be manufactured to have a curved shape using a rigid material (e.g., glass or quartz). The cover glass 40 may be seated in a lower direction (e.g., −z direction) from the second jig 920 to face the stacked structure.

As illustrated in FIG. 7, the second jig 920 and the first jig 910 may be moved toward each other. The display device 1 may be manufactured by bonding the stacked structure, including the display panel 10, the polarizing layer 20, and the adhesive layer 30, and the cover glass 40 to each other by moving the second jig 920 and the first jig 910 toward each other. For example, the second jig 920 may descend in a lower direction (e.g., −z direction). Accordingly, the cover glass 40 may press the adhesive layer 30, so that the cover glass 40 may be attached to the polarizing layer 20 and the display panel 10 through the adhesive layer 30.

In an embodiment, the adhesive layer 30 may be cured before being bonded to the cover glass 40. For example, the adhesive layer 30 may be cured by ultraviolet (UV) rays after being applied on the polarizing layer 20 and before being disposed on the first jig 910. By curing the adhesive layer 30 before the cover glass 40 is attached, the adhesive layer 30 may be prepared for bonding. For example, the adhesive layer 30 may not be further cured after the cover glass 40 is attached, and the cover glass 40 may be provided with a UV blocking function. Accordingly, the adhesive layer 30 may use an adhesive that does not require additional curing after being bonded to the cover glass 40.

As illustrated in FIG. 7, when the adhesive layer 30 is pressed, compressive stress and tensile stress may be simultaneously applied to the adhesive layer 30. For example, compressive stress and tensile stress may be simultaneously concentrated near a specific point of the adhesive layer 30. This point may be spaced apart in a ±x direction from the edges of the adhesive layer 30. For example, the point may be spaced apart from edges of the adhesive layer 30 by about 10 millimeters (mm). More specifically, in a vicinity of a point spaced apart from an −x direction edge of the adhesive layer 30 in the +x direction by about 10 mm, the adhesive layer 30 may be deformed as compressive stress in the +x direction and tensile stress in the −x direction are concentrated. In addition, in a vicinity of a point spaced apart from an +x direction edge of the adhesive layer 30 in the −x direction by about 10 mm, the adhesive layer 30 may be deformed as tensile stress in the +x direction and compressive stress in the −x direction are concentrated. If a thickness deviation of the adhesive layer 30 increases due to deformation of the adhesive layer 30, a stain may become visible in the adhesive layer 30.

In an embodiment, the adhesive layer 30, which is subject to a mechanical stress such as a compressive stress or a tensile stress, may be experience creep strain or deformation. Creep strain may be understood in terms of, for example, the Miller-Norton relationship or the Norton-Bailey model. Creep strain may be measured in terms of a percentage.

In an embodiment, a creep strain of the adhesive layer 30 may be in a range of about 15 percent to about 50 percent at about 50 degrees Celsius (° C.). When the creep strain of the adhesive layer 30 is in a range of about 15 percent to about 50 percent at about 50° C., the deformation of the adhesive layer 30 may be recovered and the thickness deviation of the adhesive layer 30 may be reduced. For example, a creep strain and a deformation of the adhesive layer 30 may decrease over time, which may reduce local variations (e.g., in a sample area) in the thickness of the adhesive layer 30. Accordingly, the adhesive layer 30 may not appear to be stained. When the creep strain of the adhesive layer 30 is less than about 15 percent at about 50° C., the deformation of the adhesive layer 30 may not be sufficiently recovered, and staining of the adhesive layer 30 may be visible. When the creep strain of the adhesive layer 30 is greater than about 50 percent at about 50° C., the adhesive layer 30 may not sufficiently perform a function of attaching, and maintaining an attachment of, the cover glass 40 to the polarizing layer 20 and the display panel 10.

In an embodiment, a storage modulus of the adhesive layer 30 may be in a range of about 0.01 megapascal (MPa) to about 0.1 MPa at about 25° C. When the storage modulus of the adhesive layer 30 is less than about 0.01 MPa at about 25° C., the adhesive layer 30 may not sufficiently perform a function of attaching, and maintaining an attachment of, the cover glass 40 to the polarizing layer 20 and the display panel 10. When the storage modulus of the adhesive layer 30 is greater than about 0.1 MPa at about 25° C., the deformation of the adhesive layer 30 may not be sufficiently recovered so that stains of the adhesive layer 30 may be visible.

In an embodiment, a storage modulus of the adhesive layer 30 may be in a range of about 0.1 MPa to about 0.5 MPa at about 0° C. When the storage modulus of the adhesive layer 30 is less than about 0.1 MPa at about 0° C., the adhesive layer 30 may not sufficiently perform a function of attaching, and maintaining an attachment of, the cover glass 40 to the polarizing layer 20 and the display panel 10. When the storage modulus of the adhesive layer 30 is greater than about 0.5 MPa at about 0° C., the deformation of the adhesive layer 30 may not be sufficiently recovered so that stains of the adhesive layer 30 may be visible.

In an embodiment, a thickness deviation of the adhesive layer 30 in the third direction (z direction) may be less than about 5 micrometers (μm). The thickness deviation may be determined in a sample area. For example, a thickness deviation of the adhesive layer 30 in an area having a width of about 3 mm in the first direction (e.g., ±x direction), which may be a width direction of the adhesive layer 30, in which the display device 1 is curved. The area may be an arbitrary area having a width of about 3 mm in the first direction (e.g., ±x direction). The thickness deviation of the adhesive layer 30, which may be a maximum thickness deviation, may be a difference between a maximum thickness of the adhesive layer 30 and a minimum thickness of the adhesive layer 30 in the area.

When the thickness deviation of the adhesive layer 30 at an arbitrary area having a width of about 3 mm in the first direction (e.g., ±x direction) is greater than or equal to about 5 μm, stains of the adhesive layer 30 may be visible. Preferably, the thickness deviation of the adhesive layer 30 at an arbitrary area having a width of about 3 mm in the first direction (e.g., ±x direction) may be less than or equal to about 2 μm.

The width of the sample area used in determining the thickness deviation may be variously selected. For example, the width of the area may be selected for achieving a representative sample, for ensuring an accurate and precise measurement of thickness deviation, and to ensure statistical relevance. Further, the sample area may have a width and a height (e.g., ty direction) for about 3 mm. For example, the sample area may be a rectangular shape. However, embodiments are not limited to the rectangular shape, and the sample area may have other shapes. One of ordinary skill in the art would recognize that the width of the sample area may be changed.

According to embodiments, staining of the adhesive layer 30 included in the curved display device 1, which may be curved in at least one direction, may be less visible. Accordingly, a display quality of the display device 1 may be improved.

Hereinafter, embodiments will be described in further detail with reference to experimental examples.

Creep strain and storage modulus of each of an adhesive layer AD1 according to comparative example and an adhesive layer AD2 according to an example embodiment are shown in Table 1 below.

TABLE 1

| | comparative example (AD1) | | example (AD2) | |
|---|---|---|---|---|
| creep strain | 1.9% | | 29.29% | |
| (at 50° C.) | | | | |
| storage modulus | 0.18 | MPa | 0.067 | MPa |
| (at 25° C.) | | | | |
| storage modulus | 8.9 | MPa | 0.286 | MPa |
| (at 0° C.) | | | | |

The creep strain of Table 1 may be obtained by measuring the deformation state of each of the adhesive layers AD1 and AD2 in a state in which a temperature is set to 50° C., a sample thickness is set to 900 micrometers (μm), a stress is set to 2000 Pa, and a creep time is set to 600 seconds in rheometer equipment (e.g., DHR-G2 from TA instruments).

In addition, example characteristics of display devices using the adhesive layers AD1 and AD2 in Table 1, respectively, are depicted in Table 2 below. More particularly, thickness of each of the adhesive layers AD1 and AD2 included in the display devices and whether or not stains may be visible are shown Table 2.

TABLE 2

| | | measuring | comparative example | | example | |
|---|---|---|---|---|---|---|
| area | section | point | (AD1) | | (AD2) | |
| A1 | thickness | P1 | 246 | μm | 249 | μm |
| | | P2 | 246 | μm | 250 | μm |
| | | P3 | 248 | μm | 250 | μm |
| | maximum thickness | | 2 | μm | 1 | μm |
| | deviation | | | | | |
| | whether or not stains | | X | | X | |
| | were visible | | | | | |
| A2 | thickness | P4 | 253 | μm | 250 | μm |
| | | P5 | 250 | μm | 250 | μm |
| | | P6 | 248 | μm | 249 | μm |
| | maximum thickness | | 5 | μm | 1 | μm |
| | deviation | | | | | |
| | whether or not stains | | ◯ (bright stain) | | X | |
| | were visible | | | | | |
| A3 | thickness | P7 | 248 | μm | 249 | μm |
| | | P8 | 250 | μm | 249 | μm |
| | | P9 | 253 | μm | 249 | μm |
| | maximum thickness | | 5 | μm | 0 | μm |
| | deviation | | | | | |
| | whether or not stains | | ◯ (dark stain) | | X | |
| | were visible | | | | | |
| A4 | thickness | P10 | 248 | μm | 248 | μm |
| | | P11 | 248 | μm | 248 | μm |
| | | P12 | 248 | μm | 248 | μm |

| | | | | |
|---|---|---|---|---|
| maximum thickness | 0 | μm | 0 | μm |

| | | |
|---|---|---|
| deviation | | |
| whether or not stains | X | X |
| were visible | | |

The comparative example may represent a stacked structure including a polarizing layer disposed on a display panel including a display substrate, an encapsulation substrate, and a seal, wherein the adhesive layer AD1 according to the comparative example in Table 1, having a thickness of about 250 μm, is disposed on the polarizing layer.

A display device according to the comparative example may be manufactured by bonding the stacked structure and a cover glass to each other using a first and second jigs, each having a seating surfaced curved with a curvature of 1000R (e.g., a bending degree of a circle having a radius of about 1000 mm) in the ±x direction. In addition, a display device according to an example embodiment may be manufactured using the adhesive layer AD2 according to the example in Table 1 under substantially same conditions as the display device according to the comparative example. Each of the display device according to the comparative example and the display device according to the example may be curved in the ±x direction.

In Table 2, the thickness of the adhesive layers AD1 and AD2 may be obtained by respectively measuring the thickness of the adhesive layers AD1 and AD2 at first to twelfth measurement points P1 to P12 spaced apart from each other in the ±x direction by 1 mm interval using a microscope (e.g., ThorImage®OCT from THORLABS instruments). Specifically, the first to twelfth measurement points P1 to P12 may be spaced apart from an −x direction edge of each display device in the +x direction by 4 mm, 5 mm, 6 mm, 7 mm, 8 mm, 9 mm, 10 mm, 11 mm, 12 mm, 13 mm, 14 mm, and 15 mm, respectively. In addition, first to fourth areas A1 to A4 may be defined to have a width of about 3 mm in the +x direction and include three adjacent measurement points. The first area A1 may be defined to include the first to third measurement points P1, P2, and P3, the second area A2 may be defined to include the fourth to sixth measurement points P4, P5, and P6, the third area A3 may be defined to include the seventh to ninth measurement points P7, P8, and P9, and the fourth area A4 may be defined to include the tenth to twelfth measurement points P10, P11, and P12. A difference between a maximum thickness and a minimum thickness of each of the adhesive layers AD1 and AD2 at the three measurement points included in each of the first to fourth areas A1 to A4 may be calculated as the maximum thickness deviation of each of the adhesive layers AD1 and AD2 at each of the first to fourth areas A1 to A4. In addition, the visibility of stains of the adhesive layers AD1 and AD2 in each of the first to fourth areas A1 to A4 may be determined with the naked eye.

In the adhesive layer AD1 included in the display device according to the comparative example, stains may not be visible in each of the first area A1 and the fourth area A4, but stains may be visible in each of the second area A2 and the third area A3. The maximum thickness deviation of the adhesive layer AD1 at the first area A1 and the fourth area A4 where stains may not be visible were 2 μm and 0 μm, respectively. The maximum thickness deviation of the adhesive layer AD1 at the second area A2 and the third area A3 where stains were not visible were 5 μm and 5 μm, respectively.

In the adhesive layer AD2 included in the display device according to an example embodiment, stains may not be visible in any of the first to fourth areas A1 to A4. Maximum thickness deviations of the adhesive layer AD2 at the first to fourth areas A1 to A4 where stains are not visible may be 1 μm, 1 μm, 0 μm, and 0 μm, respectively.

Accordingly, it can be noted that where the thickness deviation of the adhesive layer in an area having a width of 3 mm in the ±x direction in which the display device is curved was about 5 μm or more, stains of the adhesive layer may be visible.

Referring to Tables 1 and 2, in the adhesive layer AD1 according to the comparative example, since the creep strain of the adhesive layer AD1 at about 50° C. may be small and the storage modulus of the adhesive layer AD1 at each of 25° C. and 0° C. may be large, it can be noted that deformation of the adhesive layer AD1 in the second and third areas A2 and A3 may not be sufficiently recovered and stains may be visible. Whereas, in the adhesive layer AD2 according to an example embodiment, the creep strain of the adhesive layer AD2 at about 50° C. may be sufficiently large, and the storage modulus of the adhesive layer AD2 at each of 25° C. and 0° C. may be sufficiently small, such that deformation of the adhesive layer AD2 in the second and third areas A2 and A3 may be sufficiently recovered and stains may not be visible.

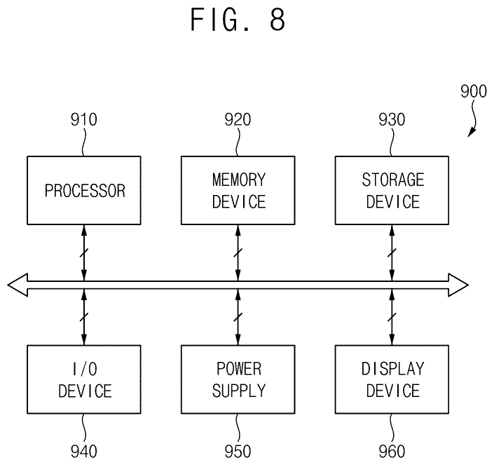

FIG. 8 is a block diagram illustrating an electronic device according to an embodiment.

Referring to FIG. 8, in an embodiment, an electronic device 900 may include a processor 910, a memory device 920, a storage device 930, an input/output (“I/O”) device 940, a power supply 950, and a display device 960. Here, the display device 960 may correspond to the display device 1 of FIGS. 1 and 2. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

Although embodiments and implementations have been described herein, other embodiments and modifications will be apparent from this description. Accordingly, the invention is not limited to any embodiment, but rather to the broader scope of the appended claims and various obvious modifications and equivalent arrangements as would be apparent to a person of ordinary skill in the art.

What is claimed is:

1. An apparatus comprising:
a display panel having a curved surface;
a cover glass disposed on the curved surface of the display panel; and
an adhesive layer disposed between the display panel and the cover glass, and
wherein a creep strain of the adhesive layer is in a range of about 15 percent to about 50 percent at about 50 degrees Celsius.

2. The apparatus of claim 1, wherein a storage modulus of the adhesive layer is in a range of about 0.01 megapascal to about 0.1 megapascal at about 25 degrees Celsius.

3. The apparatus of claim 1, wherein a storage modulus of the adhesive layer is in a range of about 0.1 megapascal to about 0.5 megapascal at about 0 degrees Celsius.

4. The apparatus of claim 1, wherein
the adhesive layer is curved in a first direction, and
a thickness deviation of the adhesive layer in a sample area is less than about 5 micrometers.

5. The apparatus of claim 4, wherein the thickness deviation of the adhesive layer is determined in the sample area having a width of about 3 millimeters in a second direction, wherein the second direction is substantially perpendicular to the first direction.

6. The apparatus of claim 1, wherein the cover glass is rigid.

7. The apparatus of claim 1, further comprising:
a polarizing layer disposed between the display panel and the adhesive layer.

8. The apparatus of claim 1, wherein the display panel comprises:
a display substrate including a base layer, a circuit element layer on the base layer, and a light emitting element layer on the circuit element layer;
an encapsulation substrate on the display substrate; and
a seal disposed between the display substrate and the encapsulation substrate, the seal surrounding the light emitting element layer in a plan view.

9. The apparatus of claim 1, wherein the display panel comprises:
a base layer;
a circuit element layer disposed on the base layer;
a light emitting element layer disposed on the circuit element layer; and
a thin film encapsulation layer disposed on the light emitting element layer.

10. An apparatus comprising:
a display panel curved in a first direction;
a cover glass disposed on the display panel and curved in the first direction; and
an adhesive layer disposed between the display panel and the cover glass and curved in the first direction, and
wherein a thickness deviation of the adhesive layer in an area having a width of about 3 millimeters in the first direction is less than about 5 micrometers.

11. The apparatus of claim 10, wherein
a creep strain of the adhesive layer is in a range of about 15 percent to about 50 percent at about 50 degrees Celsius, and
a storage modulus of the adhesive layer is in a range of about 0.01 megapascal to about 0.1 megapascal at about 25 degrees Celsius.

12. The apparatus of claim 10, wherein a storage modulus of the adhesive layer is in a range of about 0.1 megapascal to about 0.5 megapascal at about 0 degrees Celsius.

13. The apparatus of claim 10, wherein the cover glass is rigid.

14. The apparatus of claim 10, further comprising:
a polarizing layer disposed between the display panel and the adhesive layer.

15. A method of manufacturing a curved display device, the method comprising:
disposing a display panel and an adhesive layer on a first seating surface of a first jig, the first seating surface being curved in a first direction;
disposing a cover glass on a second seating surface of a second jig, the second seating surface being curved in the first direction to correspond to the first seating surface; and
moving at least one of the first jig or the second jig and bonding the display panel and the cover glass using the adhesive layer, and
wherein a creep strain of the adhesive layer bonding the display panel and the cover glass is in a range of about 15 percent to about 50 percent at about 50 degrees Celsius.

16. The method of claim 15, wherein a storage modulus of the adhesive layer is in a range of about 0.01 megapascal to about 0.1 megapascal at about 25 degrees Celsius.

17. The method of claim 15, wherein a storage modulus of the adhesive layer is in a range of about 0.1 megapascal to about 0.5 megapascal at about 0 degrees Celsius.

18. The method of claim 15, wherein a thickness deviation of the adhesive layer bonding the display panel and the cover glass at an area having a width of about 3 millimeters in the first direction is less than about 5 micrometers.

19. The method of claim 15, further comprising curing the adhesive layer before bonding the display panel and the cover glass.

20. The method of claim 15, wherein the cover glass is curved in the first direction and rigid, and
wherein a polarizing layer is disposed between the display panel and the adhesive layer.

21. An electronic device comprising:
a display device; and
a power supply configured to provide power to the display device,
wherein the display device comprises:
a display panel having a curved surface;
a cover glass disposed on the curved surface of the display panel; and
an adhesive layer disposed between the display panel and the cover glass, and
wherein a creep strain of the adhesive layer is in a range of about 15 percent to about 50 percent at about 50 degrees Celsius.
